(19) United States
(12) Patent Application Publication
(10) Pub. No.: US 2026/0036606 A1
(43) Pub. Date: Feb. 5, 2026

(54) PROBE AND SOCKET

(71) Applicant: YOKOWO CO., LTD., Tokyo (JP)

(72) Inventors: Takeshi TODOROKI, Gunma (JP); Ginta ONOZATO, Gunma (JP)

(73) Assignee: YOKOWO CO., LTD., Tokyo (JP)

(21) Appl. No.: 19/278,778

(22) Filed: Jul. 24, 2025

(30) Foreign Application Priority Data
Jul. 30, 2024 (JP) 2024-122978

(51) Int. Cl. G01R 1/067; G01R 1/04

(52) U.S. Cl. CPC G01R 1/06722; G01R 1/0466

(57) ABSTRACT

Provided are a probe that has low resistance and can cope with a large current and a socket including the probe. The probe includes a leaf spring portion and a substantially tubular portion provided at least at one end portion of the leaf spring portion, and is formed of one conductive elastic plate-shaped member.

### CROSS-REFERENCE TO RELATED APPLICATION(S)

This application is based on and claims priority under 35 USC 119 from Japanese Patent Application No. 2024-122978 filed on Jul. 30, 2024, the contents of which are incorporated herein by reference.

### TECHNICAL FIELD

The present invention relates to a probe and a socket.

### BACKGROUND ART

In general, a probe referred to as a pogo pin includes a plurality of components and has relatively high electrical resistance due to contacts between the components and a small allowable current. Such a probe is likely to be unstable due to sliding and is more expensive than a leaf spring probe.

A leaf spring probe in the related art is generally press-fitted into a housing, and the probe cannot be replaced in this case. Further, a hole for inserting the probe in the housing has a rectangular shape matching a cross section of the leaf spring, and thus a processing technique is required to form the housing as compared with a round hole.

Patent Literature 1 below discloses a contact pin formed by bending a plate-shaped conductive material into a tubular shape about an axis extending in a longitudinal direction. However, a large number of slits are formed in a middle spring portion, which increases electrical resistance of the contact pin.

### CITATION LIST

### Patent Literature

Patent Literature 1: JP2006-266869A

### SUMMARY

An example of an object of the present invention is to provide a probe that has a simple structure and low resistance and can cope with a large current, and a socket including the probe. Other objects of the present invention will become apparent based on the present description.

According to an aspect of the present invention, there is provided a probe including: a leaf spring portion; and a substantially tubular portion provided at least at one end portion of the leaf spring portion, in which the probe is formed of one conductive elastic plate-shaped member.

The probe according to the above aspect of the present invention has a simple structure and low resistance since there is no electrical contact therein, and can cope with a large current.

### BRIEF DESCRIPTION OF DRAWINGS

FIG. 1 is a perspective view of a probe 1 according to Embodiment 1 of the present invention.

FIG. 2 is an unfolded view of a conductive elastic plate-shaped member for forming the probe 1.

FIG. 3 is a front sectional view illustrating a socket 5 including the probe 1.

FIG. 4 is a perspective view of a probe 1A according to Embodiment 2 of the present invention.

FIG. 5 is a perspective view of a probe 1B according to Embodiment 3 of the present invention.

FIG. 6 is a perspective view of a probe 1C according to Embodiment 4 of the present invention.

FIG. 7 is a perspective view of a probe 1D according to Embodiment 5 of the present invention.

FIG. 8 is a perspective view of a probe 1E according to Embodiment 6 of the present invention.

FIG. 9 is an enlarged perspective view of a main portion of the probe 1E.

FIG. 10 is an unfolded view of a conductive elastic plate-shaped member for forming the probe 1E.

FIG. 11 is a perspective view of a probe 1F according to Embodiment 7 of the present invention.

FIG. 12 is an enlarged perspective view of a main portion on a front end side of the probe 1F.

FIG. 13 is an enlarged perspective view of a main portion on a rear end side of the probe 1F.

FIG. 14 is a perspective view of a probe 1G according to Embodiment 8 of the present invention.

### DESCRIPTION OF EMBODIMENTS

### Embodiment 1

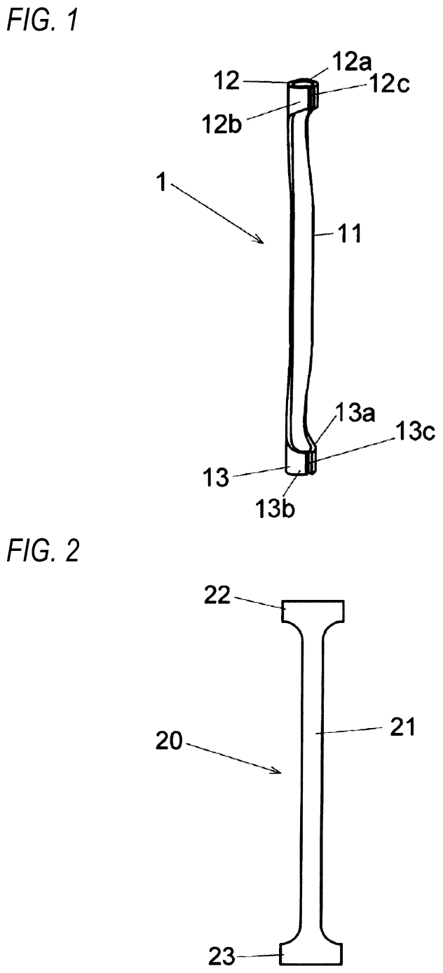

A probe 1 and a socket 5 including the probe 1 according to Embodiment 1 of the present invention will be described with reference to FIGS. 1 to 3. As illustrated in these drawings, the probe 1 includes a leaf spring portion 11 and substantially cylindrical portions 12, 13 that are tubular portions at two end portions of the leaf spring portion 11, and is formed of one conductive elastic plate-shaped member 20 illustrated in FIG. 2. The substantially cylindrical portion 12 is formed on a front end side of the probe 1, and the substantially cylindrical portion 13 is formed on a rear end side of the probe 1.

The elastic plate-shaped member 20 in FIG. 2 for manufacturing the probe 1 is a metal plate such as a copper alloy that has conductivity and flexibility, for example, phosphor bronze and beryllium copper, and includes a strip-shaped connecting portion 21 that has a constant width and forms the leaf spring portion 11 and wide end portions 22, 23 that are wider than the strip-shaped connecting portion 21 to form the substantially cylindrical portions 12, 13. By bending two sides of each of the wide end portions 22, 23 in an arc shape by sheet metal processing, as illustrated in FIG. 1, the substantially cylindrical portions 12, 13 are formed at the two end portions of the leaf spring portion 11 implemented by the strip-shaped connecting portion 21. The substantially cylindrical portion 12 includes a pair of arc portions 12a, 12b, and the substantially cylindrical portion 13 includes a pair of arc portions 13a, 13b. The pair of arc portions 12a, 12b and the pair of arc portions 13a, 13b are respectively provided with slits 12c, 13c in butt portions thereof.

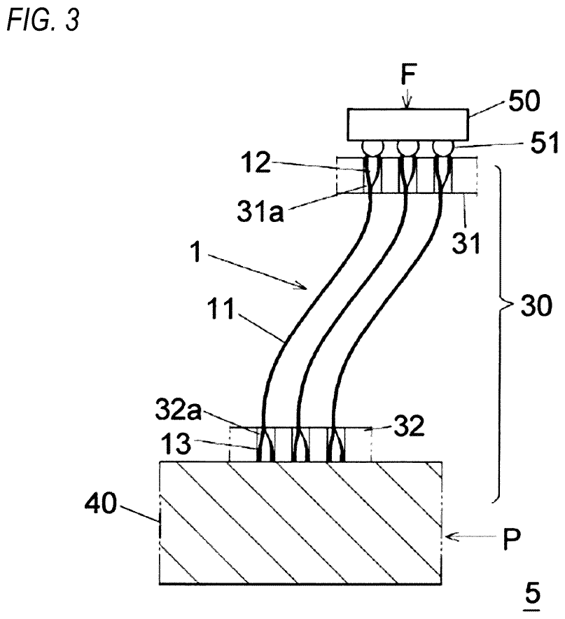

As illustrated in FIG. 3, the socket 5 includes a plurality of probes 1, a housing portion 30 made of a non-elastic and rigid insulating hard material, and an inspection board 40 fixed to a bottom surface of the housing portion 30. The housing portion 30 includes a first support member 31 having insertion holes 31a in which the substantially cylindrical portions 12, which are front end portions of the probes 1, are disposed, and a second support member 32 having insertion holes 32a in which the substantially cylindrical portions 13, which are rear end portions of the probes 1, are disposed. The first and second support members 31, 32 are held at a constant interval. The insertion holes 31a, 32a are round holes that are easily processed and formed, and support the substantially cylindrical portions 12, 13 such that the substantially cylindrical portions 12, 13 are movable, for example, slidable in an upper-lower direction without rattling. The inspection board 40 includes electrode pads that come into electrical contact with the substantially cylindrical portions 13 of the probes 1, and the electrode pads are not illustrated.

The socket 5 is assembled, for example, in following procedures. The plurality of probes 1 in a state in which the leaf spring portions 11 in FIG. 1 are straight in a longitudinal direction are inserted into the insertion holes 31a, 32a of the first and second support members 31, 32 before position fixing. At this time, insertion postures of the probes 1 are aligned in advance so that width directions of the leaf spring portions 11 of the plurality of probes 1 are substantially perpendicular to a paper surface of FIG. 3. Next, a positional relationship between the first and second support members 31, 32 is fixed in a state of FIG. 3 in which the second support member 32 is shifted in a direction of an arrow P (leftward direction in the paper surface) relative to the first support member 31 and the leaf spring portions 11 of the probes 1 are bent in the same direction. By bending the leaf spring portions 11 in the same direction in advance, the leaf spring portions 11 of the probes 1 are bent in the same direction during measurement in which the probes 1 are pressed by bumps (solder balls or the like) 51 that are electrodes of an under-measurement device 50. As a result, the insertion holes 31a, 32a can have a small arrangement pitch, in other words, the probes 1 can have a small arrangement interval.

When the under-measurement device 50 is measured, the under-measurement device 50 is placed on the socket 5, the bumps 51 of the under-measurement device 50 are brought into contact with the substantially cylindrical portions 12 that are front end side contact portions, and a load F is applied in a direction of an arrow F (downward direction in the paper surface). The substantially cylindrical portions 12 of the probes 1 protruding from the housing portion 30 are pressed down by the load F, and deflection amounts of the leaf spring portions 11 increase, whereby the probes 1 can absorb height variations of the bumps 51 while generating a required contact pressure on the bumps 51. At the same time, the substantially cylindrical portions 13 that are rear end side contact portions come into contact with the electrode pads of the inspection board 40 at a required contact pressure.

According to the present embodiment, following effects can be achieved.

(1) The probe 1 is formed of one conductive elastic plate-shaped member 20, and includes the leaf spring portion 11 and the substantially cylindrical portions 12, 13 that are contact portions on two sides thereof. For this reason, the probe 1 is a single component having a simple structure and low cost with no contact or sliding portion therein. Accordingly, the probe 1 has low and stable electrical resistance and can cope with a large allowable current.

(2) The elastic plate-shaped member 20 for manufacturing the probe 1 includes the strip-shaped connecting portion 21 having a constant width, which forms the leaf spring portion 11 having a constant cross-sectional area at a cross section thereof due to a constant width of the leaf spring portion 11, making it possible to avoid local concentration of bending stress applied to the probe 1 during measurement of an under-measurement device in FIG. 3.

(3) The housing portion 30 of the socket 5 includes the first support member 31 having the insertion holes 31a in which the substantially cylindrical portions 12, which are front end portions of the probes 1, are disposed, and the second support member 32 having insertion holes 32a in which the substantially cylindrical portions 13, which are rear end portions of the probes 1, are disposed. The insertion holes 31a, 32a may be round holes corresponding to the substantially cylindrical portions 12, 13. For this reason, the probes 1 can be easily processed and replaced.

(4) When the insertion holes 31a, 32a of the housing portion 30 are round holes and the respective two end portions of the leaf spring portions 11 of the probes 1 remain in a thin plate shape, positions in the round holes are not stable, and forming the substantially cylindrical portions 12, 13 that are substantially tubular portions at the respective two end portions of the probes 1 makes the positions in the round holes stabilized. This makes it possible to cope with a case where an interval between electrodes of the under-measurement device 50 is small.

(5) In the housing portion 30, the probes 1 are supported in a state in which the leaf spring portions 11 are bent in the same direction, so that the leaf spring portions 11 of the probes 1 are bent in the same direction during measurement of the under-measurement device 50. As a result, contact between the adjacent leaf spring portions 11 can be avoided and the insertion holes 31a, 32a can have a small arrangement pitch.

### Embodiment 2

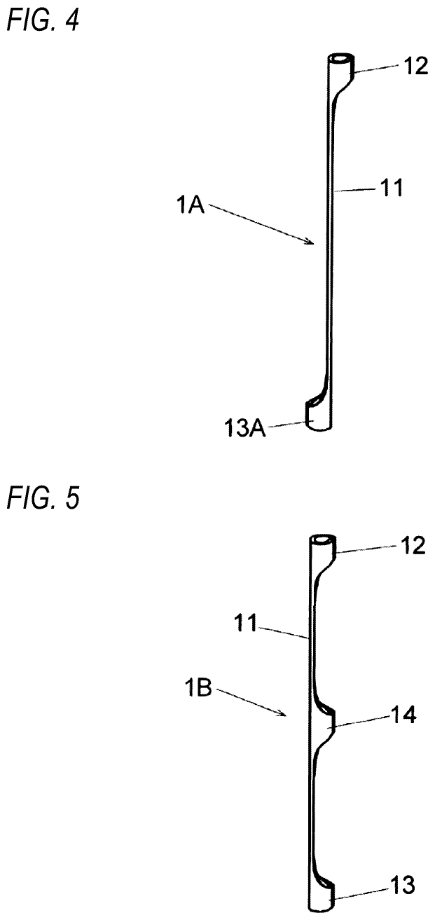

FIG. 4 illustrates a probe 1A according to Embodiment 2 of the present invention. In this case, the probe 1A is different from that in Embodiment 1 in that the probe 1A includes the leaf spring portion 11 and substantially cylindrical portions 12, 13A at two end portions thereof, and that the substantially cylindrical portions 12, 13A have opposite formation directions relative to the leaf spring portion 11. According to Embodiment 2, the leaf spring portion 11 is easier to bend than that in Embodiment 1. Other configurations and effects are the same as those of Embodiment 1.

### Embodiment 3

FIG. 5 illustrates a probe 1B according to Embodiment 3 of the present invention. In this case, the probe 1B has a structure in which a substantially cylindrical portion 14 is formed at a middle portion of the leaf spring portion 11. The substantially cylindrical portion 14 at the middle portion is not bent, and thus a spring length is actually smaller, and a value of spring pressure of the probe during inspection of an under-measurement device is larger as compared with a probe without the substantially cylindrical portion 14 at the middle portion. Other configurations are the same as those of Embodiment 1. In the probe 1B, the value of the spring pressure can be adjusted by forming the substantially cylindrical portion 14 at the middle portion of the leaf spring portion 11. Other functions and effects are the same as those of Embodiment 1.

### Embodiment 4

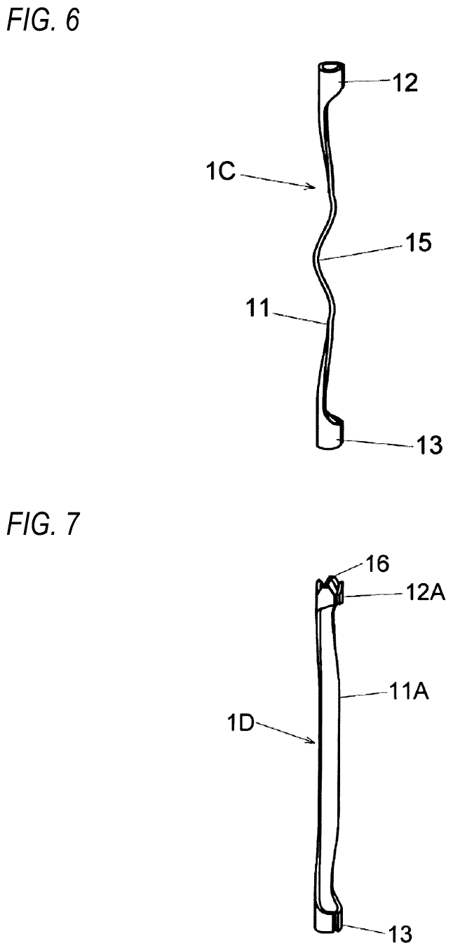

FIG. 6 illustrates a probe 1C according to Embodiment 4 of the present invention. In this case, the probe 1C has a structure in which a curved portion 15 curved along the longitudinal direction is formed at a middle portion of the leaf spring portion 11. Other configurations are the same as those of Embodiment 1. In the probe 1C, since the curved portion 15 is formed at the middle portion of the leaf spring portion 11, a bending direction can be set in advance and a value of spring pressure can be adjusted. Other functions and effects are the same as those of Embodiment 1.

### Embodiment 5

FIG. 7 illustrates a probe 1D according to Embodiment 5 of the present invention. In this case, the substantially cylindrical portion 12A, which is one end of the probe 1D, includes a chevron front end portion 16 formed in a chevron shape at a front end edge, which enables contact with a bump of an under-measurement device. Other configurations are the same as those of Embodiment 1 in FIG. 1. Since the front end edge of the probe 1D is formed in a chevron shape, which matches the shape of the bump of the under-measurement device, a contact property can be improved. Other functions and effects are the same as those of Embodiment 1.

### Embodiment 6

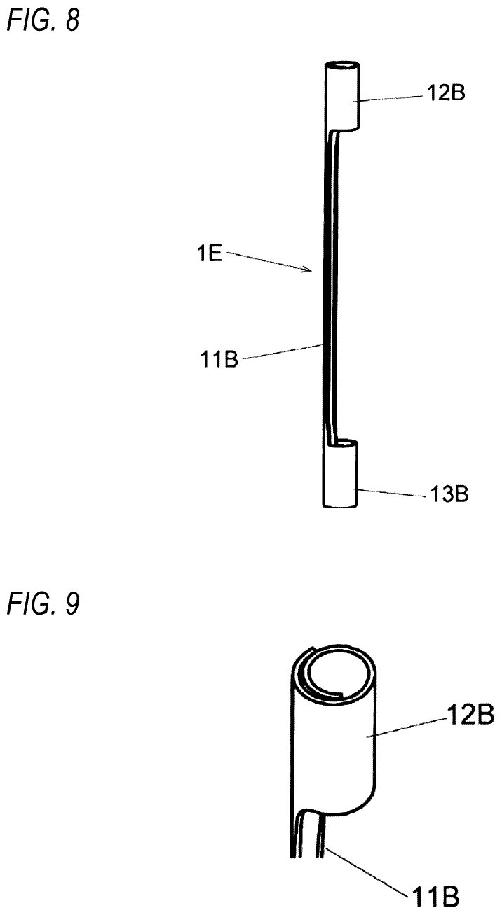

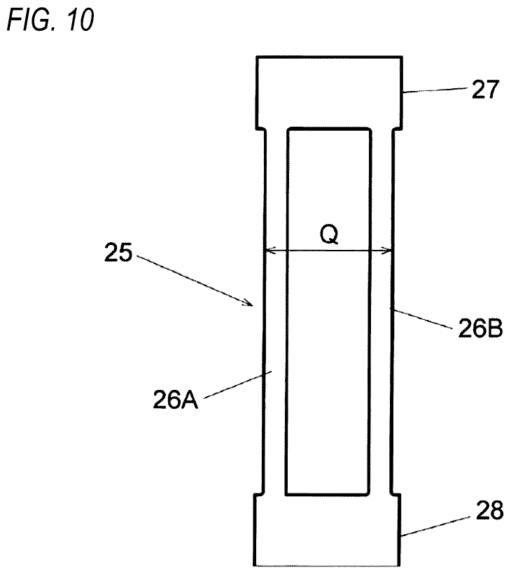

A probe 1E according to Embodiment 6 of the present invention will be described with reference to FIGS. 8 to 10. As illustrated in these drawings, the probe 1E includes a leaf spring portion 11B in which a metal plate is overlapped into two layers, and substantially cylindrical portions 12B, 13B at two ends of the leaf spring portion 11B. As illustrated in FIG. 10, the probe 1E is formed of one conductive elastic plate-shaped member 25. The substantially cylindrical portion 12B is a front end portion that comes into contact with a bump of a measurement device, and the substantially cylindrical portion 13B is a rear end portion that comes into contact with an electrode pad of an inspection board.

The elastic plate-shaped member 25 in FIG. 10 for manufacturing the probe 1E is a metal plate such as a copper alloy that has conductivity and flexibility, for example, phosphor bronze and beryllium copper, and includes a pair of strip-shaped connecting portions 26A, 26B that have a constant width and form the leaf spring portion 11B, and wide end portions 27, 28 that are wider than a distance Q between outer edges of the strip-shaped connecting portions 26A, 26B and are continuous with the strip-shaped connecting portions 26A, 26B. The wide end portions 27, 28 are portions for forming the substantially cylindrical portions 12B, 13B. By winding the wide end portions 27, 28 in annular shapes by sheet metal processing, as illustrated in FIG. 9, the substantially cylindrical portion 12B having a portion of the wide end portion 27 overlapped into two layers is formed. Similarly to the substantially cylindrical portion 12B, the substantially cylindrical portion 13B having a portion of the wide end portion 28 overlapped into two layers is formed. The wide end portions 27, 28 are rounded such that the strip-shaped connecting portions 26A, 26B overlap each other. A portion where the strip-shaped connecting portions 26A, 26B overlap each other is the leaf spring portion 11B.

According to Embodiment 6, when the leaf spring portion 11 according to Embodiment 1 and the leaf spring portion 11B having the same thickness (a sum of thicknesses of the strip-shaped connecting portions 26A, 26B) as the leaf spring portion 11 are compared, the leaf spring portion 11B overlapped into two layers is easier to bend. Accordingly, a value of spring pressure of the probe can be reduced as compared with Embodiment 1. Other functions and effects are the same as those of Embodiment 1.

### Embodiment 7

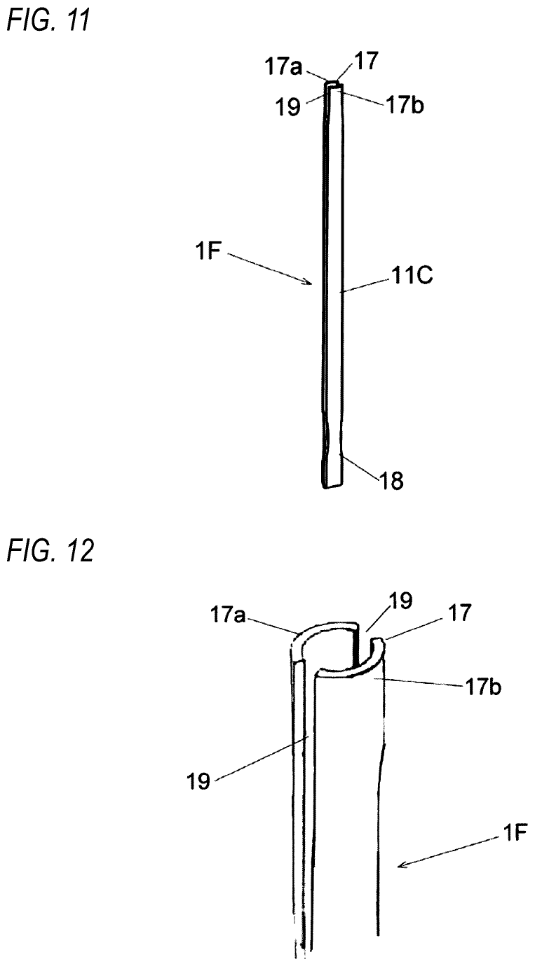

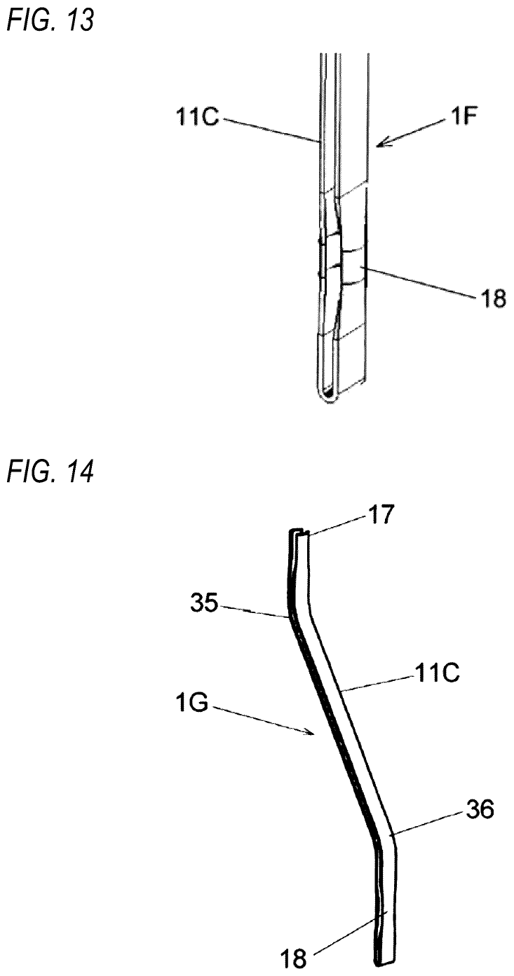

FIG. 11 illustrates a probe 1F according to Embodiment 7 of the present invention. The probe 1F has a configuration in which an elongated elastic plate-shaped member is folded in half and overlapped in a middle position in the longitudinal direction. The elastic plate-shaped member includes a leaf spring portion 11C formed in a folded and overlapped shape and substantially tubular portions 17, 18 at two end portions thereof. As illustrated in FIG. 12, the substantially tubular portion 17 includes arc portions 17a, 17b facing each other through slits 19, and has a substantially tubular shape as a whole. As illustrated in FIG. 13, the substantially tubular portion 18 on a rear end side also includes arc structures facing each other similarly to the substantially tubular portion 17, but for convenience of processing, the substantially tubular portion 18 is located closer to the leaf spring portion 11C than to a rear end position where the elastic plate-shaped member is folded. The substantially tubular portion 17 is a front end portion that comes into contact with a bump of a measurement device, and the substantially tubular portion 18 is in a position in a vicinity of a rear end portion that comes into contact with an electrode pad of an inspection board.

According to Embodiment 7, when the leaf spring portion 11 according to Embodiment 1 and the half-folded and overlapped leaf spring portion 11C having the same thickness (the same cross-sectional area as the leaf spring portion 11) as the leaf spring portion 11 are compared, the half-folded and overlapped leaf spring portion 11C is easier to bend, and thus a value of spring pressure of the probe can be made smaller than that of Embodiment 1 even when electrical resistance is the same. The substantially tubular portion 17 and the substantially tubular portion 18 can be easily formed by sheet metal processing before the elongated elastic plate-shaped member is folded and overlapped. Other functions and effects are the same as those of Embodiment 1.

### Embodiment 8

FIG. 14 illustrates a probe 1G according to Embodiment 8 of the present invention. In this case, the probe 1G includes bent portions 35, 36 that are gently bent in the longitudinal direction of a middle portion of the half-folded and overlapped leaf spring portion 11C. Other configurations are the same as those of Embodiment 8 in FIG. 12. According to Embodiment 9, the bent portions 35, 36 are formed in advance at the middle portion of the leaf spring portion 11C, so that the leaf spring portion 11C can be easily bent and bending directions can be aligned. Other functions and effects are the same as those of Embodiment 1.

Although embodiments and modifications of the present invention have been described above with reference to the drawings, these embodiments and modifications are examples of the present invention, and various configurations other than those described above can also be used.

In Embodiment 1 in FIG. 1 or the like, the substantially cylindrical portion 12 is formed as the front end portion of the probe 1, and the substantially cylindrical portion 13 is formed as the rear end portion of the probe 1. Alternatively, shapes of the substantially cylindrical portions are not limited to a substantially cylindrical shape, and may be another tubular shape inscribed in a round hole of a housing portion of a socket, for example, a polygonal tubular shape and a shape in which an arc portion includes an arc portion having a small diameter therein. When a sheet metal is processed into a polygonal tubular shape, R that is approximately twice a plate thickness, that is, a radius in a bending position, is generated during bending. Accordingly, a corner of a polygonal tube has a shape that is not sharp but rounded. Further, lengths of the substantially tubular portion at the front end portion and the substantially tubular portion at the rear end portion may not be the same. A shape of a portion of the substantially tubular portion at the front end portion which comes into contact with an electrode of an under-measurement device can be appropriately changed to a crown shape, a conical shape, and the like.

In the probe 1E according to Embodiment 6 in FIGS. 8 to 10, the two strip-shaped connecting portions 26A, 26B having a constant width are formed on an elastic plate-shaped member 25, so that the leaf spring portion 11B having a double-layer structure in which the strip-shaped connecting portions 26A, 26B overlap each other is formed. Alternatively, a leaf spring portion having a multi-layer structure may be formed by providing three or more strip-shaped connecting portions that form a leaf spring portion.

In Embodiment 1 in FIG. 1 or the like, the substantially cylindrical portion 12 is formed as the front end portion of the probe 1, and the substantially cylindrical portion 13 is formed as the rear end portion of the probe 1. Alternatively, depending on conditions such as an area and an arrangement pitch of electrode pads of an inspection board, the substantially cylindrical portion 13 at the rear end portion may be omitted and an end portion of the leaf spring portion 11 may come into contact with the electrode pad of the inspection board.

In Embodiment 3 in FIG. 5, the substantially cylindrical portion 14 is formed at the middle portion of the leaf spring portion 11. Alternatively, to substantially shorten the leaf spring portion, for example, a bent portion having a substantially L-shaped cross section may be formed at the middle portion. Further, the value of the spring pressure can be adjusted by changing a lateral width of the leaf spring portion at an intermediate portion.

Although the socket 5 includes the probe 1 in FIG. 1, the probe 1A according to Embodiment 2 in FIG. 4, the probe 1B according to Embodiment 3 in FIG. 5, the probe 1C according to Embodiment 4 in FIG. 6, the probe 1D according to Embodiment 5 in FIG. 7, the probe 1E according to Embodiment 6 in FIG. 8, the probe 1F according to Embodiment 7 in FIG. 11, or the probe 1G according to Embodiment 8 in FIG. 14 can be used instead of the probe 1.

Although the socket 5 in FIG. 3 has been described as including the inspection board 40, the socket may not include the inspection board. For example, an inspection board may be provided in another device, and a socket including no inspection board may be installed on the inspection board of the other device.

In the housing portion 30 of the socket 5 in FIG. 3, the first and second insertion holes 31a, 32a of the first and second support members 31, 32 in which end portions of the probes 1 are disposed are shifted from each other in planar position. Alternatively, the first and second insertion holes 31a, 32a in which the end portions of the probes 1 are disposed may be aligned in planar position. For example, since the probe 1C according to Embodiment 4 in FIG. 6 has a structure in which the curved portion 15 is formed at the middle portion of the leaf spring portion 11, planar positions of the first and second insertion holes 31a, 32a are aligned. In this case, by aligning directions of the curved portions 15 of the probes 1C, an arrangement pitch of the insertion holes 31a, 32a can be reduced, in other words, an arrangement interval of the probes 1C can be reduced.

According to the present specification, there is provided a probe and a socket according to following aspects.

### Aspect 1

A probe includes:
a leaf spring portion; and
a substantially tubular portion provided at least at one end portion of the leaf spring portion, in which
the probe is formed of one conductive elastic plate-shaped member.

According to Aspect 1, it is possible to cope with a large current with a simple structure and low resistance since there is no electrical contact therein.

### Aspect 2

In the probe, a portion of the elastic plate-shaped member which forms the leaf spring portion has a strip shape having a constant lateral width.

According to Aspect 2, the leaf spring portion has a constant cross-sectional area at a cross section due to a constant width thereof, making it possible to avoid local concentration of bending stress applied to the probe during measurement of an under-measurement device.

### Aspect 3

In the probe, the substantially tubular portion has a substantially cylindrical or substantially rectangular tubular outer shape.

According to Aspect 3, when insertion holes of a housing portion are round holes and two end portions of the leaf spring portion of the probe remain in a thin plate shape, positions in the round holes are not stable, and forming the substantially tubular portions having a substantially cylindrical or substantially rectangular tubular outer shape at the two end portions of the probe can make the positions in the round holes stabilized.

### Aspect 4

In the probe, the leaf spring portion has a multi-layer structure in which portions of the elastic plate-shaped member which form the leaf spring portion overlap.

According to Aspect 4, the leaf spring portion has a structure in which a plurality of portions of the elastic plate-shaped member which form the leaf spring portion overlap each other, and is easier to bend than a leaf spring portion having the same thickness, making it possible to reduce a value of spring pressure.

### Aspect 5

In the probe, the leaf spring portion has a structure in which a portion of the elastic plate-shaped member which forms the leaf spring portion is folded and overlapped, and the substantially tubular portion includes arc portions facing each other.

According to Aspect 5, a portion of the elastic plate-shaped member which forms the leaf spring portion is folded and overlapped, and is easier to bend than one leaf spring portion having the same thickness. Accordingly, the value of the spring pressure can be reduced. The substantially tubular portion can also be easily formed by sheet metal working.

### Aspect 6

In the probe, a substantially tubular portion is formed at a middle portion of the leaf spring portion.

According to Aspect 6, the substantially tubular portion formed at the middle portion of the leaf spring portion is not bent. Accordingly, the leaf spring portion is substantially shortened, and the value of the spring pressure of the probe during inspection of an under-measurement device can be increased.

### Aspect 7

In the probe, a curved portion or a gently bent portion is formed at the leaf spring portion.

According to Aspect 7, a curved portion or a gently bent portion is formed, making it possible to align a bending direction of the leaf spring portion. Further, the leaf spring portion can be easily bent, and the value of the spring pressure can be reduced.

### Aspect 8

A socket includes:
the probe according to claim 1;
a first support having a first insertion hole in which one end portion of the probe is disposed; and
a second support having a second insertion hole in which the other end portion of the probe is disposed.

According to Aspect 8, it is possible to implement a socket having features of a probe such as a simple structure, low resistance, and capable of coping with a large current. Further, the probe can be replaced.

### Aspect 9

In the socket, planar positions of the first insertion hole and the second insertion hole in which the end portions of the probe are disposed are shifted from each other.

According to Aspect 9, the probe is supported in a state in which the leaf spring portion is bent in the same direction, so that the leaf spring portion of the probe is bent in the same direction during measurement of an under-measurement device. As a result, an arrangement pitch of the first and second insertion holes can be reduced.

### Aspect 10

In the socket, the first insertion hole and the second insertion hole are round holes.

According to Aspect 10, the first and second insertion holes are round holes corresponding to the substantially tubular portion. Accordingly, drilling of the first and second support members is easy.

1. A probe comprising:
a leaf spring portion; and
a substantially tubular portion provided at least at one end portion of the leaf spring portion, wherein
the probe is formed of one conductive elastic plate-shaped member.

2. The probe according to claim 1, wherein a portion of the elastic plate-shaped member which forms the leaf spring portion has a strip shape having a constant lateral width.

3. The probe according to claim 1, wherein the substantially tubular portion has a substantially cylindrical or substantially rectangular tubular outer shape.

4. The probe according to claim 1, wherein the leaf spring portion has a multi-layer structure in which portions of the elastic plate-shaped member which form the leaf spring portion overlap.

5. The probe according to claim 1, wherein the leaf spring portion has a structure in which a portion of the elastic plate-shaped member which forms the leaf spring portion is folded and overlapped, and the substantially tubular portion includes arc portions facing each other.

6. The probe according to claim 1, wherein a substantially tubular portion is formed at a middle portion of the leaf spring portion.

7. The probe according to claim 1, wherein a curved portion or a gently bent portion is formed at the leaf spring portion.

8. A socket comprising:
the probe according to claim 1;
a first support having a first insertion hole in which one end portion of the probe is disposed; and
a second support having a second insertion hole in which the other end portion of the probe is disposed.

9. The socket according to claim 8, wherein planar positions of the first insertion hole and the second insertion hole in which the end portions of the probe are disposed are shifted from each other.

10. The socket according to claim 8, wherein the first insertion hole and the second insertion hole are round holes.
